(19) United States
(12) Patent Application Publication
(10) Pub. No.: US 2025/0028238 A1
(43) Pub. Date: Jan. 23, 2025

(54) METHOD FOR MANUFACTURING PELLICLE AND PELLICLE MANUFACTURED THEREBY

(71) Applicant: GrapheneLab.Co.,Ltd, Hwaseong-si (KR)

(72) Inventors: Seung Il MOON, Ansan-si (KR); Young Duck KWON, Gwangmyeong-si (KR); Byong Wook YOO, Namyangju-si (KR); Jong Taik MOON, Seongnam-si (KR); Ki Soo KIM, Seongnam-si (KR); Sang Min LEE, Yongin-si (KR)

(21) Appl. No.: 18/905,122

(22) Filed: Oct. 2, 2024

Related U.S. Application Data
(63) Continuation of application No. PCT/KR2023/004144, filed on Mar. 29, 2023.

(30) Foreign Application Priority Data
Apr. 4, 2022 (KR) 10-2022-0041468

(51) Int. Cl. G03F 1/62; G03F 7/00; G03F 7/40

(52) U.S. Cl. CPC G03F 1/62; G03F 7/0005; G03F 7/40

(57) ABSTRACT

A method for manufacturing the pellicle includes the steps of forming upper and lower silicon nitride layers on opposite surfaces of a wafer substrate, forming a metal layer on the lower silicon nitride layer, etching the upper silicon nitride layer to a preset thickness after the forming of the metal layer, etching and removing the metal layer after the etching of the upper silicon nitride layer, forming a graphene thin film on the upper silicon nitride layer, forming a pattern on the lower silicon nitride layer, etching the lower silicon nitride layer according to the formed pattern, and etching the wafer substrate along the lower silicon nitride layer etched according to the pattern.

### CROSS-REFERENCE TO RELATED APPLICATIONS

This application is a Continuation of International Application No. PCT/KR2023/004144 filed Mar. 29, 2023, which claims priority from Korean Application no. 10-2022-0041468 filed Apr. 4, 2022. The aforementioned applications are incorporated herein by reference in their entireties.

### TECHNICAL FIELD

The present disclosure relates generally to a method for manufacturing a pellicle and a pellicle manufactured thereby. More particularly, the present disclosure relates to a method for manufacturing a pellicle having a silicon nitride thin film formed with a thickness of equal to or less than 5 nm using an etching method, and to a pellicle manufactured thereby.

### RELATED ART

In the manufacture of semiconductor devices, etc., a photolithography method is used to pattern a semiconductor wafer substrate. In the photolithography method, a photomask is used as a base plate for patterning.

Light is transmitted through a photomask, which is a patterning base plate, to transfer a pattern to a wafer substrate. When dust, etc. is adhered to the photomask, the light is absorbed or reflected by the dust, so the mask pattern may not be transferred to the wafer substrate or the transferred pattern may be damaged, causing a decrease in performance of a semiconductor device or an increase in defect rate. Also, even when the process is performed in a clean room, dust, etc. inevitably exists, making it difficult to prevent this problem from occurring.

To prevent such a phenomenon in which dust adheres to a photomask, there is used a method of attaching a pellicle so that dust is not directly adhered to a surface of the photomask but rather to the pellicle.

Due to the pellicle attached, light focus is positioned on a pattern of the photomask during lithography, so dust adhered to the pellicle is not focused and is not transferred as a pattern onto a wafer substrate.

Meanwhile, as semiconductor devices, etc. become more highly integrated, patterns formed by lithography become finer. To cope with this, the wavelength of a light source becomes shorter, so recently, methods using extreme ultraviolet (EUV) have been frequently proposed.

However, since EUV has high energy, it is difficult to apply it by changing the properties of a thin pellicle. To solve this problem, there has recently been proposed a pellicle manufacturing method of depositing a silicon nitride layer on opposite surfaces of a wafer substrate, sequentially forming a single crystal or polycrystalline silicon layer as a core layer with high extreme ultraviolet transmittance, a silicon nitride layer, and a capping layer on the silicon nitride layer on an upper surface of the wafer substrate, applying a photoresist to the silicon nitride layer formed on a lower surface of the wafer substrate and patterning it, and removing a central portion of the silicon nitride layer by dry etching and removing a central portion of the wafer substrate by wet etching to form a window through which EUV is transmitted.

Additionally, research has been conducted on using a graphene layer with high thermal conductivity and low EUV absorption rate as a core layer.

However, increasing the transmittance of EUV in the pellicle requires a thin film to have a small thickness. The silicon nitride film deposited on the wafer substrate generally has a thickness of about 100 nm and it is technically difficult to realize a thickness of equal to or less than 100 nm. Even when it is technically possible to deposit a thickness of equal to or less than 100 nm, the thickness may be limited to 10 to 50 nm and deposition reliability may not be guaranteed.

Additionally, the thickness of a silicon nitride layer in a pellicle actually used needs to be less than 5 nm, but due to technical limitations, the silicon nitride layer is deposited thickly. Therefore, the silicon nitride layer is etched again in a deposited membrane state. However, this method is problematic in that its success rate is very low because the silicon nitride layer is required to be etched in a state of being a thin membrane to make it less than 5 nm thick, resulting in a very low yield of the pellicle.

### SUMMARY

Accordingly, the present disclosure has been made keeping in mind the above problems occurring in the related art, and an objective of the present disclosure is to provide a method for manufacturing a pellicle having high EUV transmittance and production yield by etching a deposited silicon nitride layer in a stable state to equal to or less than 5 nm without etching the silicon nitride layer in a state of being a thin membrane, and provide a pellicle manufactured thereby.

In order to accomplish the above objective, according to one aspect of the present disclosure, there is provided a method for manufacturing a pellicle, the method including: forming upper and lower silicon nitride layers on opposite surfaces of a wafer substrate; forming a pattern on the lower silicon nitride layer; etching the lower silicon nitride layer according to the formed pattern; forming a metal layer on the lower silicon nitride layer; etching the upper silicon nitride layer to a preset thickness after the forming of the metal layer; etching and removing the metal layer after the etching of the upper silicon nitride layer; forming a graphene thin film on the upper silicon nitride layer; and etching the wafer substrate along the lower silicon nitride layer etched according to the pattern.

Meanwhile, according to another aspect of the present disclosure, there is provided a method for manufacturing a pellicle, the method including: forming upper and lower silicon nitride layers on opposite surfaces of a wafer substrate; forming a metal layer on the lower silicon nitride layer; etching the upper silicon nitride layer to a preset thickness after the forming of the metal layer; etching and removing the metal layer after the etching of the upper silicon nitride layer; forming a pattern on the lower silicon nitride layer; etching the lower silicon nitride layer according to the formed pattern; forming a graphene thin film on the upper silicon nitride layer; and etching the wafer substrate along the lower silicon nitride layer etched according to the pattern.

Thereby, it may be possible to solve the conventional problem in which it is difficult to deposit a silicon nitride layer with a thickness of equal to or less than 100 nm and deposition reliability is not guaranteed even when the above thickness range is achieved. Also, the silicon nitride layer may be etched to a thickness of equal to or less than 5 nm in a stable state, i.e., in a state in which a metal layer is formed, rather than in a state of being a thin membrane, thereby dramatically increasing the pellicle yield.

Additionally, the forming of the pattern on the lower silicon nitride layer may be performed by forming the pattern on the lower silicon nitride layer through a photolithography process, and the etching of the lower silicon nitride may be performed by dry etching according to the formed pattern.

Thereby, when the upper silicon nitride layer is etched to a thickness of equal to or less than 5 nm, the lower silicon nitride layer may be protected by the metal layer so as not to be etched. Therefore, it may be possible to solve the problem in which when a silicon wafer substrate is etched by potassium hydroxide (KOH), the lower silicon nitride layer has no ability to protect the silicon wafer substrate when its thickness is equal to or less than 5 nm, making patterning impossible.

Additionally, a metal of the metal layer may be resistant to an etchant for etching the upper silicon nitride layer. More specifically, the etchant for etching the upper silicon nitride layer may be a solution containing hydrogen fluoride, and the metal of the metal layer may be an alloy of at least one metal selected from the group consisting of Ni, Ti, Mo Cr, Fe, and Cu.

Thereby, when the upper silicon nitride layer is etched, the metal of the metal layer may be prevented from being etched. Therefore, it may be possible to solve the conventional problem in which the yield is poor because of the need to etch the upper silicon nitride layer to a thickness of 5 nm in a state of being a membrane. Also, the lower silicon nitride layer may be protected by the metal layer, i.e., a sufficient thickness may be secured, so the silicon wafer substrate may be stably protected when etched by potassium hydroxide, enabling stable patterning.

Additionally, a pellicle may be manufactured by the above method.

Thereby, it may be possible to obtain a pellicle that is thin, has excellent mechanical properties, has good EUV transmittance, and has dramatically increased production yield.

According to the present disclosure, it is possible to solve the conventional problem in which it is difficult to deposit a silicon nitride layer with a thickness of equal to or less than 100 nm and deposition reliability is not guaranteed even when the above thickness range is achieved. Also, the silicon nitride layer can be etched to a thickness of equal to or less than 5 nm in a stable state, i.e., in a state in which a metal layer is formed, rather than in a state of being a thin membrane, thereby dramatically increasing the pellicle yield.

Additionally, when an upper silicon nitride layer is etched to a thickness of equal to or less than 5 nm, the lower silicon nitride layer can be protected by the metal layer so as not to be etched. Therefore, it is possible to solve the problem in which when a silicon wafer substrate is etched by potassium hydroxide (KOH), a lower silicon nitride layer has no ability to protect the silicon wafer substrate when its thickness is equal to or less than 5 nm, making patterning impossible.

Additionally, when the upper silicon nitride layer is etched, a metal of the metal layer can be prevented from being etched. Therefore, it is possible to solve the conventional problem in which the yield is poor because of the need to etch the upper silicon nitride layer to a thickness of 5 nm in a state of being a membrane. Also, the lower silicon nitride layer can be protected by the metal layer, i.e., a sufficient thickness can be secured, so the silicon wafer substrate can be stably protected when etched by potassium hydroxide, enabling stable patterning.

### BRIEF DESCRIPTION OF THE DRAWINGS

FIG. 1 is a flowchart illustrating a method for manufacturing a pellicle according to a preferred embodiment of the present disclosure.

FIG. 2 illustrates conceptual diagrams illustrating the method for manufacturing the pellicle illustrated in FIG. 1.

FIG. 3 is a flowchart illustrating a method for manufacturing a pellicle according to another preferred embodiment of the present disclosure.

FIG. 4 illustrates conceptual diagrams illustrating the method for manufacturing the pellicle illustrated in FIG. 3.

### DETAILED DESCRIPTION

The above and other objectives, features, and advantages of the present disclosure will be clearly understood from the more particular description of exemplary embodiments of the present disclosure. The present disclosure may, however, be embodied in different forms and should not be construed as limited to the embodiments set forth herein. Rather, these embodiments are provided so that this disclosure is thorough and complete and fully conveys the present disclosure to those skilled in the art.

It will be understood that, when an element is referred to as being on another element, it can be formed directly on the other element or intervening elements may be present therebetween. Further, in the drawings, the thicknesses of elements may be exaggerated for effective explanation of technical contents.

It will be understood that, although the terms first, second, etc. may be used herein to describe various elements, these elements should not be limited by these terms. These terms are only used to distinguish one element from another. The embodiments described and illustrated herein include their complementary embodiments.

Further, it should be understand that when a first element (or component) is referred to as being operated or executed on a second element (or component), the first element (or component) is operated or executed in the environment in which a second element (or component) is operated or executed, or the second element (or component) is operated or executed through direct or indirect interaction.

It should be understand that when an element, component, device, or system is referred to as including a component composed of a program or software, the element, component, device, or system includes hardware (e.g., memory, CPU, etc.) necessary for the program or software to execute or operate, or other programs or software (e.g., drivers necessary to run an operating system or hardware), unless otherwise specified.

Further, it should be understood that in the implementation of an element (or component), the element (or component) may be implemented in software, hardware, or any form of software and hardware, unless otherwise specified.

The terminology used herein is for the purpose of describing particular embodiments only and is not intended to be limiting. As used herein, the singular forms are intended to include the plural forms as well, unless the context clearly indicates otherwise. It will be further understood that the terms “comprises” and/or “comprising”, when used herein, do not preclude the presence or addition of one or more other elements.

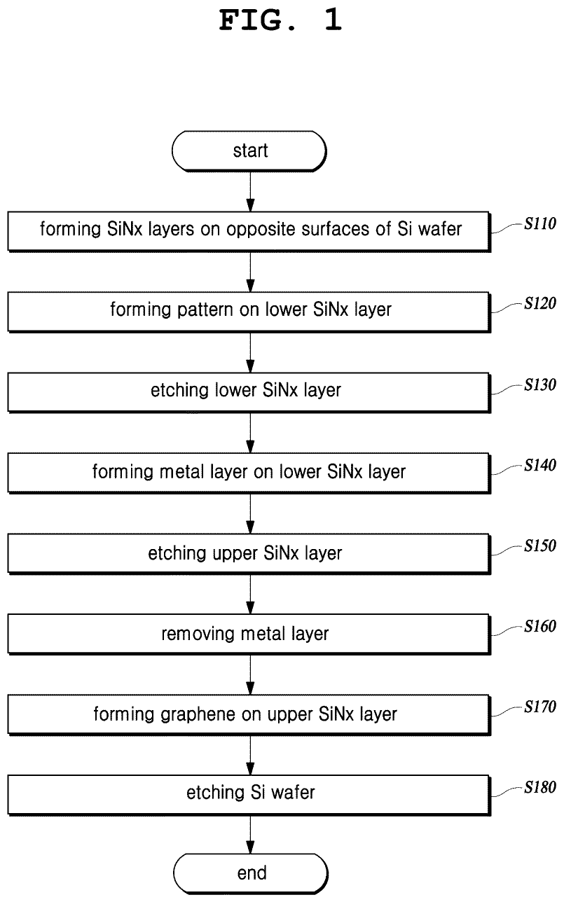

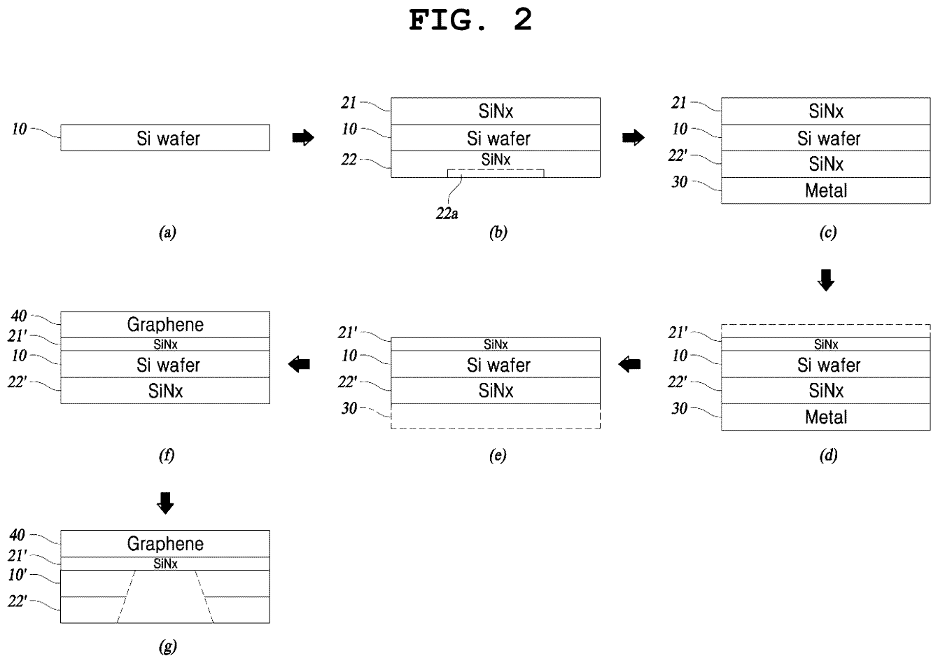

FIG. 1 is a flowchart illustrating a method for manufacturing a pellicle according to a preferred embodiment of the present disclosure. FIG. 2, panels (a) to (g) are conceptual diagrams illustrating the method for manufacturing the pellicle illustrated in FIG. 1.

Hereinbelow, a method for manufacturing a pellicle according to a preferred embodiment of the present disclosure will be described in detail with reference to FIGS. 1 and 2.

As illustrated in FIG. 1, the method for manufacturing the pellicle according to the preferred embodiment of the present disclosure includes: forming upper and lower silicon nitride layers 21 and 22 on opposite surfaces of a wafer substrate 10 (S110); forming a pattern 22a on the lower silicon nitride layer 22 (S120); etching the lower silicon nitride layer 22′ according to the formed pattern 22a (S130); forming a metal layer 30 on the lower silicon nitride layer 22′ (S140); etching the upper silicon nitride layer 21 to a preset thickness after the forming of the metal layer 30 (S140) (S150); etching and removing the metal layer 30 after the etching of the upper silicon nitride layer 21 (S160); forming a graphene thin film 40 on the upper silicon nitride layer 21′ (S170); and etching the wafer substrate 10 along the lower silicon nitride layer 22′ etched according to the pattern 22a (S180).

Describing each step, as illustrated in FIG. 2 panels (a) and (b), first, the upper and lower silicon nitride layers 21 and 22 are formed on the opposite surfaces of the wafer substrate 10 (S110).

The upper and lower silicon nitride layers 21 and 22 may be deposited through a chemical vapor deposition (CVD) process, a physical vapor deposition (PVD) process, a low pressure CVD (LPCVD) process, or an atomic layer deposition (ALD) process.

Conventionally, the upper and lower silicon nitride layers 21 and 22 had to be deposited thinly because of their low extreme ultraviolet (EUV) transmittance, which required high technical difficulty and resulted in low yield. However, in the present disclosure, sensitivity to a thickness to be deposited is not high, making it possible to achieve high yield.

Then, the pattern 22a is formed on the lower silicon nitride layer 22. At this time, the pattern 22a may be stably formed on the lower silicon nitride layer 22 while having a sufficient thickness (S120).

Then, the lower silicon nitride layer 22′ is etched according to the formed pattern 22a (S130).

Then, as illustrated in panel (c) of FIG. 2, the metal layer 30 is formed on the lower silicon nitride layer 22′ (S140).

The metal layer 30 may be formed through a process such as sputtering or vacuum deposition, and it is preferable that the metal layer is a metal that is resistant to an etchant for etching the upper silicon nitride layer 21, which will be described later. Therefore, the lower silicon layer 22′ may be protected by the metal layer 30 when the upper silicon layer 21 is etched.

Then, as illustrated in panel (d) of FIG. 2, the upper silicon nitride layer 21 is etched to a preset thickness (S150).

After the metal layer 30 is deposited on the lower silicon nitride layer 22′, the upper silicon nitride layer 21 may be etched with a solution containing hydrogen fluoride to have a preset thickness. The metal layer 30 enables the upper silicon nitride layer 21 to be etched in a stable state rather than a membrane state, thereby dramatically increasing the yield. The lower silicon nitride layer 22′ is protected by the metal layer 30 and is patterned to enable the wafer substrate 10 to be etched, as will be described later.

At this time, when the upper silicon nitride layer 21 is etched by the solution containing hydrogen fluoride, the metal layer 30 protecting the lower silicon nitride layer 22′ is preferably made of an alloy of at least one metal selected from the group consisting of nickel (Ni), titanium (Ti), molybdenum (Mo), chromium (Cr), iron (Fe), and copper (Cu) so as to be resistant to hydrogen fluoride and not be etched.

Then, as illustrated in panel (e) of FIG. 2, the upper silicon nitride layer 21 is etched to a preset thickness and then the metal layer 30 is etched and removed (S160).

Etching of the metal layer 30 uses a mixture solution based on nitric acid as an etchant. In some embodiments, a mixture containing iron chloride (FeCl₃) or iron nitrate (Fe(NO₃)) may be used.

Then, as illustrated in panel (f) of FIG. 2, the graphene thin film 40 is formed on the upper silicon nitride layer 21′ processed to be thin by etching (S170).

Graphene has high transparency, good mechanical strength, and excellent thermal conductivity, and when used in pellicles, it may have high mechanical strength while having a sufficiently small thickness.

According to some embodiments, it may be formed as single-layer graphene, few-layer graphene, or multi-layer graphene, and may be formed by a method such as chemical vapor deposition (CVD), physical vapor deposition (PVD), atomic layer deposition (ALD), high-density CVD (HDCVD), or plasma-enhanced CVD (PECVD).

Then, as illustrated in panel (g) of FIG. 2, the wafer substrate 10 is etched along the lower silicon nitride layer 22′ etched according to the pattern 22a to form a window (S180).

After patterning the lower silicon nitride layer 22′, the central portion thereof is removed by dry etching. The central portion of the wafer substrate 10 is removed by wet etching to form a window through which extreme ultraviolet (EUV) light is transmitted, thereby finally obtaining a pellicle.

By the above method, when forming the upper and lower silicon nitride layers 21 and 22 on the opposite surfaces of the wafer substrate, even when these silicon nitride layers are formed thickly without any limitation on thickness, the upper silicon nitride layer may be etched to be thin while maintaining a stable state (supported by the metal layer), thereby securing the EUV transmittance of the final pellicle. Also, when the upper silicon nitride layer 21 is etched, the thickness of the lower silicon nitride layer 22 may be protected, so the lower silicon nitride layer may stably protect the wafer substrate and be patterned to form a window.

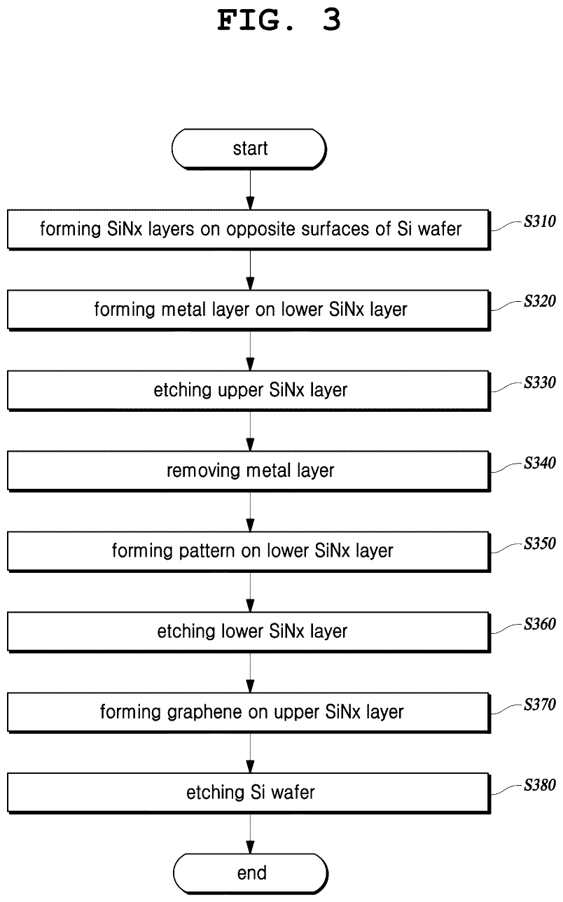

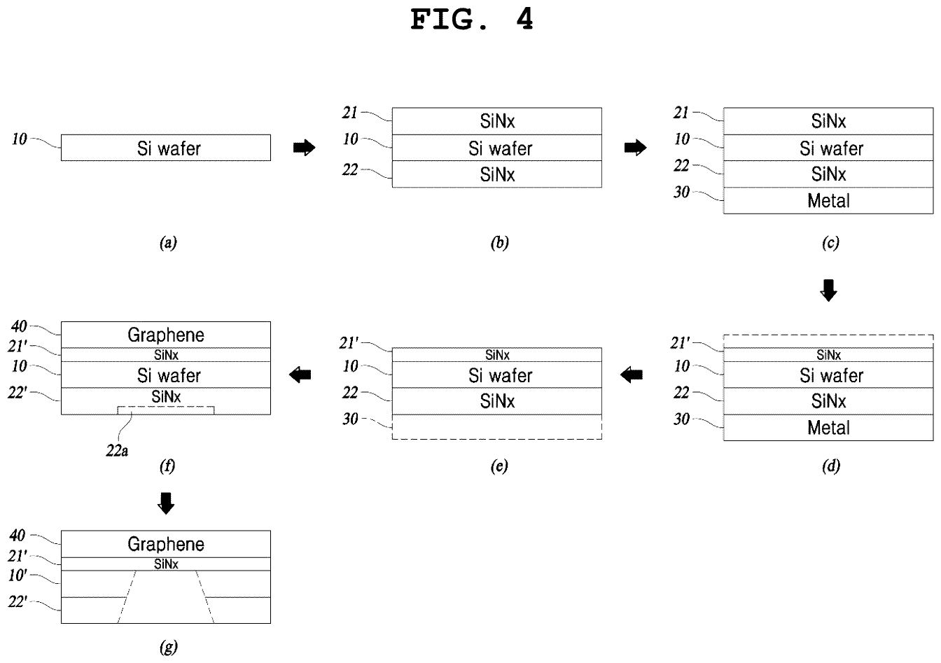

FIG. 3 is a flowchart illustrating a method for manufacturing a pellicle according to another preferred embodiment of the present disclosure. FIG. 4, panels (a) to (g) are conceptual diagrams illustrating the method for manufacturing the pellicle illustrated in FIG. 3.

Hereinbelow, a method for manufacturing a pellicle according to another preferred embodiment of the present disclosure will be described in detail with reference to FIGS. 3 and 4.

As illustrated in FIG. 3, the method for manufacturing the pellicle according to the other preferred embodiment of the present disclosure includes: forming upper and lower silicon nitride layers 21 and 22 on opposite surfaces of a wafer substrate 10 (S310); forming a metal layer 30 on the lower silicon nitride layer 22 (S320); etching the upper silicon nitride layer 21 to a preset thickness after the forming of the metal layer 30 (S330); etching and removing the metal layer 30 after the etching of the upper silicon nitride layer 21 (S340); forming a pattern 22a on the lower silicon nitride layer 22 (S350); etching the lower silicon nitride layer 22′ according to the formed pattern 22a (S360); forming a graphene thin film 40 on the upper silicon nitride layer 21′ (S370); and etching the wafer substrate 10 along the lower silicon nitride layer 22′ etched according to the pattern 22a (S380).

Describing each step, as illustrated in FIG. 4 panels (a) and (b), first, the upper and lower silicon nitride layers 21 and 22 are formed on the opposite surfaces of the wafer substrate 10 (S310).

The upper and lower silicon nitride layers 21 and 22 may be deposited through a chemical vapor deposition (CVD) process, a physical vapor deposition (PVD) process, a low pressure CVD (LPCVD) process, or an atomic layer deposition (ALD) process.

Conventionally, the upper and lower silicon nitride layers 21 and 22 had to be deposited thinly because of their low extreme ultraviolet (EUV) transmittance, which required high technical difficulty and resulted in low yield. However, in the present disclosure, sensitivity to a thickness to be deposited is not high, making it possible to achieve high yield.

Then, as illustrated in panel (c) of FIG. 4, the metal layer 30 is formed on the lower silicon nitride layer 22 (S320).

The metal layer 30 may be formed through a process such as sputtering or vacuum deposition, and it is preferable that the metal layer is a metal that is resistant to an etchant for etching the upper silicon nitride layer 21, which will be described later. Therefore, the lower silicon layer 22 may be protected by the metal layer 30 when the upper silicon layer 21 is etched.

Then, as illustrated in panel (d) of FIG. 4, the upper silicon nitride layer 21 is etched to a preset thickness (S340).

After the metal layer 30 is deposited on the lower silicon nitride layer 22, the upper silicon nitride layer 21 may be etched with a solution containing hydrogen fluoride to have a preset thickness. The metal layer 30 enables the upper silicon nitride layer 21 to be etched in a stable state rather than a membrane state, thereby dramatically increasing the yield. The lower silicon nitride layer 22 is protected by the metal layer 30 and patterned to enable a silicon wafer to be etched, as will be described later.

At this time, when the upper silicon nitride layer 21 is etched by the solution containing hydrogen fluoride, the metal layer 30 protecting the lower silicon nitride layer 22 is preferably made of an alloy of at least one metal selected from the group consisting of nickel (Ni), titanium (Ti), molybdenum (Mo), chromium (Cr), iron (Fe), and copper (Cu) so as to be resistant to hydrogen fluoride and not be etched.

Then, as illustrated in panel (e) of FIG. 4, the upper silicon nitride layer 21 is etched to a preset thickness and then the metal layer 30 is etched and removed (S340).

Etching of the metal layer 30 uses a mixture solution based on nitric acid as an etchant. In some embodiments, a mixture containing iron chloride (FeCl₃) or iron nitrate (Fe(NO₃)) may be used.

Then, as illustrated in (f) of FIG. 4, the pattern 22a is formed on the lower silicon nitride layer 22 (S350).

Since the lower silicon nitride layer 22 is protected by the metal layer 30 when the upper silicon nitride layer 21 is etched with the solution containing hydrogen fluoride, the lower silicon nitride layer may maintain a sufficient thickness and allow the pattern 22a to be formed due to its stable thickness.

Then, the lower silicon nitride layer 22 is etched according to the pattern 22a (S360), and the graphene thin film 40 is formed on the upper silicon nitride layer 21′ processed to be thin by etching (S370).

Graphene has high transparency, good mechanical strength, and excellent thermal conductivity, and when used in pellicles, it may have high mechanical strength while having a sufficiently small thickness.

According to some embodiments, it may be formed as single-layer graphene, few-layer graphene, or multi-layer graphene, and may be formed by a method such as chemical vapor deposition (CVD), physical vapor deposition (PVD), atomic layer deposition (ALD), high-density CVD (HDCVD), or plasma-enhanced CVD (PECVD).

Then, as illustrated in panel (g) of FIG. 2, the wafer substrate 10 is etched along the lower silicon nitride layer 22 etched according to the pattern 22a to form a window (S380).

After patterning the lower silicon nitride layer 22, the central portion thereof is removed by dry etching. The central portion of the wafer substrate 10 is removed by wet etching to form a window through which extreme ultraviolet (EUV) light is transmitted, thereby finally obtaining a pellicle.

By the above method, when forming the upper and lower silicon nitride layers 21 and 22 on the opposite surfaces of the wafer substrate 10, even when these silicon nitride layers are formed thickly without any limitation on thickness, the upper silicon nitride layer 21 may be etched to be thin while maintaining a stable state (supported by the metal layer), thereby securing the EUV transmittance of the final pellicle. Also, when the upper silicon nitride layer 21 is etched, the thickness of the lower silicon nitride layer 22 may be protected, so the lower silicon nitride layer may stably protect the wafer substrate and be patterned to form a window.

### DESCRIPTION OF THE REFERENCE NUMERALS IN THE DRAWINGS

10: wafer substrate
21: upper silicon nitride layer
21′: etched upper silicon nitride layer
22: lower silicon nitride layer
22′: patterned lower silicon nitride layer
30: metal layer
40: graphene layer

What is claimed is:

1. A method for manufacturing a pellicle, the method comprising:
forming upper and lower silicon nitride layers on upper and lower surfaces of a wafer substrate, respectively;
forming a pattern on the lower silicon nitride layer;
etching the lower silicon nitride layer according to the formed pattern;
forming a metal layer on the lower silicon nitride layer;
etching the upper silicon nitride layer to a preset thickness after the forming of the metal layer;
etching and removing the metal layer after the etching of the upper silicon nitride layer;
forming a graphene thin film on the upper silicon nitride layer; and
etching the wafer substrate along the lower silicon nitride layer etched according to the pattern.

2. The method of claim 1, wherein the forming of the pattern on the lower silicon nitride layer is performed by forming the pattern on the lower silicon nitride layer through a photolithography process, and
wherein the etching of the lower silicon nitride is performed by dry etching according to the formed pattern.

3. The method of claim 1, wherein a metal of the metal layer is resistant to an etchant for etching the upper silicon nitride layer.

4. The method of claim 2, wherein a metal of the metal layer is resistant to an etchant for etching the upper silicon nitride layer.

5. The method of claim 3, wherein the etchant for etching the upper silicon nitride layer is a solution containing hydrogen fluoride, and wherein the metal of the metal layer is an alloy of at least one metal selected from the group consisting of Ni, Ti, Mo Cr, Fe, and Cu.

6. The method of claim 4, wherein the etchant for etching the upper silicon nitride layer is a solution containing hydrogen fluoride, and
wherein the metal of the metal layer is an alloy of at least one metal selected from the group consisting of Ni, Ti, Mo Cr, Fe, and Cu.

7. A pellicle manufactured by the method of claim 1.

8. A pellicle manufactured by the method of claim 5.

9. A pellicle manufactured by the method of claim 6.

10. A method for manufacturing a pellicle, the method comprising:
forming upper and lower silicon nitride layers on upper and lower surfaces of a wafer substrate, respectively;
forming a metal layer on the lower silicon nitride layer;
etching the upper silicon nitride layer to a preset thickness after the forming of the metal layer;
etching and removing the metal layer after the etching of the upper silicon nitride layer;
forming a pattern on the lower silicon nitride layer;
etching the lower silicon nitride layer according to the formed pattern;
forming a graphene thin film on the upper silicon nitride layer; and
etching the wafer substrate along the lower silicon nitride layer etched according to the pattern.

11. The method of claim 10, wherein the forming of the pattern on the lower silicon nitride layer is performed by forming the pattern on the lower silicon nitride layer through a photolithography process, and
wherein the etching of the lower silicon nitride is performed by dry etching according to the formed pattern.

12. The method of claim 10, wherein a metal of the metal layer is resistant to an etchant for etching the upper silicon nitride layer.

13. The method of claim 11, wherein a metal of the metal layer is resistant to an etchant for etching the upper silicon nitride layer.

14. The method of claim 12, wherein the etchant for etching the upper silicon nitride layer is a solution containing hydrogen fluoride, and
wherein the metal of the metal layer is an alloy of at least one metal selected from the group consisting of Ni, Ti, Mo Cr, Fe, and Cu.

15. The method of claim 13, wherein the etchant for etching the upper silicon nitride layer is a solution containing hydrogen fluoride, and
wherein the metal of the metal layer is an alloy of at least one metal selected from the group consisting of Ni, Ti, Mo Cr, Fe, and Cu.

16. A pellicle manufactured by the method of claim 10.

17. A pellicle manufactured by the method of claim 14.

18. A pellicle manufactured by the method of claim 15.
